(19) United States
(12) Patent Application Publication
(10) Pub. No.: US 2017/0059798 A1
(43) Pub. Date: Mar. 2, 2017

(54) EMI SHIELD TO SUPPRESS EMI LEAKAGE FROM ONE OR MORE OPTICAL PORTS OF AN OPTICAL COMMUNICATIONS MODULE

(71) Applicant: Avago Technologies General IP (Singapore) Pte. Ltd., Singapore (SG)

(72) Inventors: Robert Ritter, Los Altos, CA (US); Frank Yashar, Cupertino, CA (US); Venkatesh Seetharam, Fremont, CA (US); Sunil Priyadarshi, Sunnyvale, CA (US)

(21) Appl. No.: 14/839,107

(22) Filed: Aug. 28, 2015

(51) Int. Cl. G02B 6/42; H05K 9/00; H05K 5/04

(52) U.S. Cl. CPC G02B 6/4277; G02B 6/4249; H05K 5/04; H05K 9/0058

(57) ABSTRACT

In one exemplary embodiment, an optical communications module includes an upper housing portion mated to a lower housing portion with an optical port projecting through an opening in a front surface of the mated assembly. Electronic circuit housed inside the mated assembly can lead to electromagnetic interference (EMI) leakage through a front surface of the mated assembly, especially through the opening that accommodates the optical port. An EMI shield, which is used to address the EMI leakage, includes an annular array of resilient metal fingers that press against a metal flange of the optical port, and also includes at least two peripheral edges each incorporating an array of resilient metal fingers that press against a metal portion of the mated assembly. An interdigital spacing in the annular array and/or the array of resilient metal fingers is defined on the basis of a wavelength associated with the EMI radiation.

### FIELD OF THE INVENTION

The invention relates to EMI shielding, and more particularly, to an EMI shield that prevents EMI leakage from one or more optical ports in an optical communications module.

### BACKGROUND

The U.S. Federal Communications Commission (FCC), which is one of several such similar organizations around the world, defines and enforces standards directed at limiting the amount of electromagnetic interference (EMI) emissions out of various electronic and electrical products. EMI emissions are generally undesirable as they can lead to malfunctioning of other electronic and electrical products that are adversely impacted when exposed to interference from unwanted radio frequency (RF) signals. However, it is difficult and expensive to provide EMI shielding elements that entirely eliminate EMI emissions out of products, such as, for example, optical communications modules. The difficulty mainly arises from challenges associated with creating EMI shielding elements that effectively conform to the individual shapes and sizes of assorted holes and openings located at various places in these products.

For example, EMI emissions may take place out of a hole that has been provided in an optical communications module for inserting an optical cable used for propagating optical signals into or out of the optical communications module. While it may be relatively simple to seal such a hole for preventing moisture or air from entering the optical communications module, it is more complicated to provide an EMI shield that prevents EMI emissions generated by electrical circuitry that may be contained inside the optical communications module from leaking out through this hole.

As another example, EMI emissions may take place out of an opening formed between two mating parts of an optical communications module. The opening may have been specifically provided for purposes of accommodating a connector. However, EMI emissions can leak out from gaps between the body of the connector and the sides of the opening. It is desirable that such EMI emission leaks be prevented, or at least attenuated as much as possible.

Unfortunately, various traditional solutions for EMI shielding of holes and openings such as those described above, have proven inadequate or inefficient, and it is therefore desirable to address at least some of these traditional shortcomings.

### BRIEF DESCRIPTION OF THE FIGURES

Many aspects of the invention can be better understood by referring to the following description in conjunction with the accompanying claims and figures. Like numerals indicate like structural elements and features in the various figures. For clarity, not every element may be labeled with numerals in every figure. The drawings are not necessarily drawn to scale, emphasis instead being placed upon illustrating the principles of the invention. The drawings should not be interpreted as limiting the scope of the invention to the example embodiments shown herein.

FIG. 1 shows an exemplary embodiment of an optical communications module that includes two optical ports.

FIG. 2 shows a first perspective view of various exemplary components mounted in a lower housing portion of the optical communications module shown in FIG. 1, the various components including an EMI shield used for blocking EMI emissions from around the two optical ports in accordance with the disclosure.

FIG. 3 shows a second perspective view of various exemplary components mounted in the lower housing portion of the optical communications module shown in FIG. 1, the various components including the EMI shield in accordance with the disclosure.

FIG. 4 shows a third perspective view of the various exemplary components of the optical communications module that are shown in FIG. 3, with the lower housing portion removed.

FIG. 5 shows a fourth perspective view of the various exemplary components of the optical communications module that are shown in FIG. 4, including a view of a rear portion of the EMI shield shown in FIG. 4.

FIG. 6 shows an obverse-side close-up perspective view of the EMI shield configured to provide EMI shielding around the two optical ports in accordance with the disclosure.

FIG. 7 shows a reverse-side close-up perspective view of the EMI shield shown in FIG. 6.

FIG. 8 shows a close-up view of the EMI shield mounted in the lower housing portion of the optical communications module in accordance with the disclosure.

FIG. 9 shows a cross-sectional side view of the EMI shield mounted inside the optical communications module in accordance with the disclosure.

FIG. 10 shows a cross-sectional top view of the EMI shield mounted inside the optical communications module in accordance with the disclosure.

### DETAILED DESCRIPTION

Throughout this description, embodiments and variations are described for the purpose of illustrating uses and implementations of inventive concepts. The illustrative description should be understood as presenting examples of inventive concepts, rather than as limiting the scope of the concept as disclosed herein. It should be further understood that certain words and terms are used herein solely for convenience and such words and terms should be interpreted as referring to various objects and actions that are generally understood in various forms and equivalencies by persons of ordinary skill in the art. For example, it should be understood that the phrase “optical port” generally refers to a part of an optical communications module that is configured to mate with various external components such as, for example, an optical connector disposed at the end of an optical cable. It should also be understood that the word “example” as used herein is intended to be non-exclusionary and non-limiting in nature. More particularly, the word “exemplary” as used herein indicates one among several examples, and it must be understood that no undue emphasis or preference is being directed to the particular example being described.

Generally, in accordance with a first illustrative embodiment, an optical communications module includes an upper housing portion mated to a lower housing portion with two optical ports projecting through two openings in a front surface of the mated assembly. The lower housing portion accommodates an electronic circuit assembly that can lead to a leakage of electromagnetic interference (EMI) from the front surface, particularly from the two openings that accommodate the two optical ports. An electromagnetic interference (EMI) shield in accordance with the disclosure is used to provide EMI shielding on the front surface to address the EMI leakage.

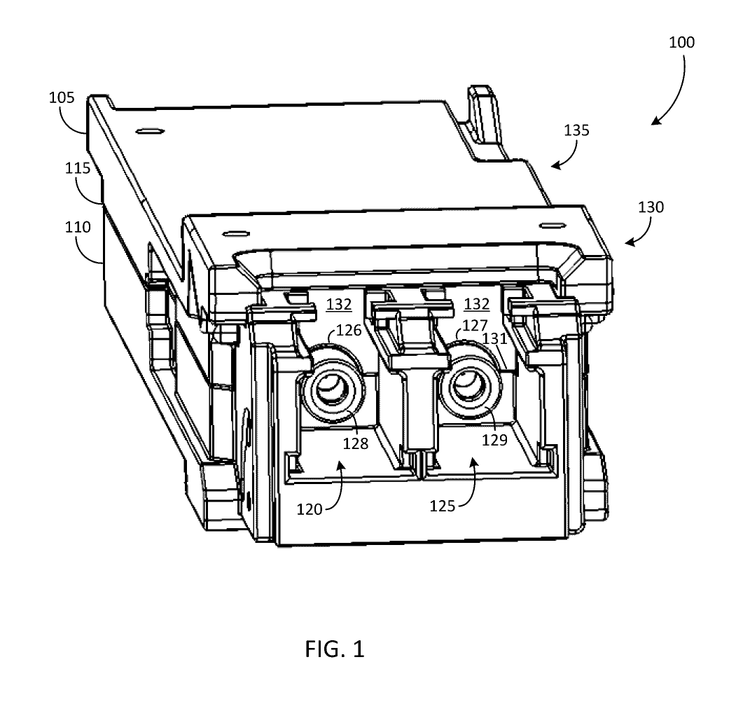

Attention is now drawn to FIG. 1, which shows an exemplary embodiment of an optical communications module 100. In accordance with this illustrative embodiment, the optical communications module 100 is a small form-factor pluggable (SFP) or enhanced SFP (SFP+) optical communications module. However, the invention is not limited to SFP or SFP+ optical communications modules and can be implemented in various other optical communications modules. The optical communications module 100 includes a front housing portion 130 coupled to a rear housing portion 135. The front housing portion 130 includes a first receptacle area 120 and a second receptacle area 125. The first receptacle area 120 provides room for connecting a first optical cable or other connection element (not shown) to a first optical port 128. The second receptacle area 125 provides room for connecting a second optical cable or other connection element (not shown) to a second optical port 129. The rear housing portion 135 of the optical communications module 100 includes a lower housing portion 110 and an upper housing portion 105. In one example implementation, each of the lower housing portion 110 and the upper housing portion 105 is made entirely, or in part, of a metal, although non-metallic materials may be used in other implementations.

The lower housing portion 110 and the upper housing 105 can be provided in the form of a pivot and snap feature that allows the two portions to be mated with each together. Such a mating can result in a gap 115 that extends around the periphery of the optical communications module 100. In some implementations, an adhesive material may be placed on the gap 115 and a curing procedure used for curing the adhesive material. Even if the adhesive material is applied in such a manner so as to block all portions of the gap 115, this adhesive material, which is typically non-metallic in composition, fails to operate as an effective EMI shield. Consequently, one or more external EMI shielding elements (not shown) can be used to block EMI leakage out of the gap 115.

However, EMI leakage is not limited to the gap 115, and can leak out through various other openings of the optical communications module 100 as well as directly through various non-metallic surfaces. One area of the optical communications module 100 that is particularly vulnerable to EMI emissions is the front surface 132 of the front housing portion 130, which includes the first receptacle area 120 and the second receptacle area 125.

A portion of each of the first optical port 128 and the second optical port 129 projects out of the front surface 132 via respective openings that have been provided for this purpose. Specifically, a cylindrical body portion of the first optical port 128 projects out of the optical communications module 100 through a first circular opening 126. In this exemplary embodiment, the first circular opening 126 is formed by abutting a semicircular opening provided in a wall of the upper housing portion 105 with a corresponding semicircular opening provided in a wall of the lower housing portion 110. Similarly, a second circular opening 127 is formed by abutting another semicircular opening provided in the wall of the upper housing portion 105 with another corresponding semicircular opening provided in the wall of the lower housing portion 110.

In view of manufacturing tolerances and other factors, a first gap can exist between the cylindrical body portion of the first optical port 128 and the inner periphery of the first circular opening 126. A second gap can be similarly present between the cylindrical body portion of the second optical port 129 and the inner periphery of the second circular opening 127. EMI emissions can leak out of the optical communications module 100 not only through these two gaps but through other gaps, such as, for example, a seam 131 where the upper housing portion 105 abuts the lower housing portion 110. Furthermore, in some cases, EMI emissions can also directly leak out of the front surface 132 when electronic circuitry contained inside the optical communications module 100 is operated at certain regions of the radio-frequency (RF) spectrum.

For example, in one example implementation, the optical communications module 100 may contain electronic circuitry operating in the Gigahertz (GHz) range of RF frequencies. Such frequencies can readily propagate out of non-metallic surfaces as well as some types of ungrounded metallic surfaces. For example, a portion of one or both of the first optical port 128 and the second optical port 129 (an ungrounded metal body portion, for example) may act as an RF radiator element that radiates EMI. It is therefore desirable that EMI shielding be provided to not only block EMI emissions out of the front surface 132 as well as various openings in the front surface 132, but to also ground various portions of the first optical port 128 and the second optical port 129.

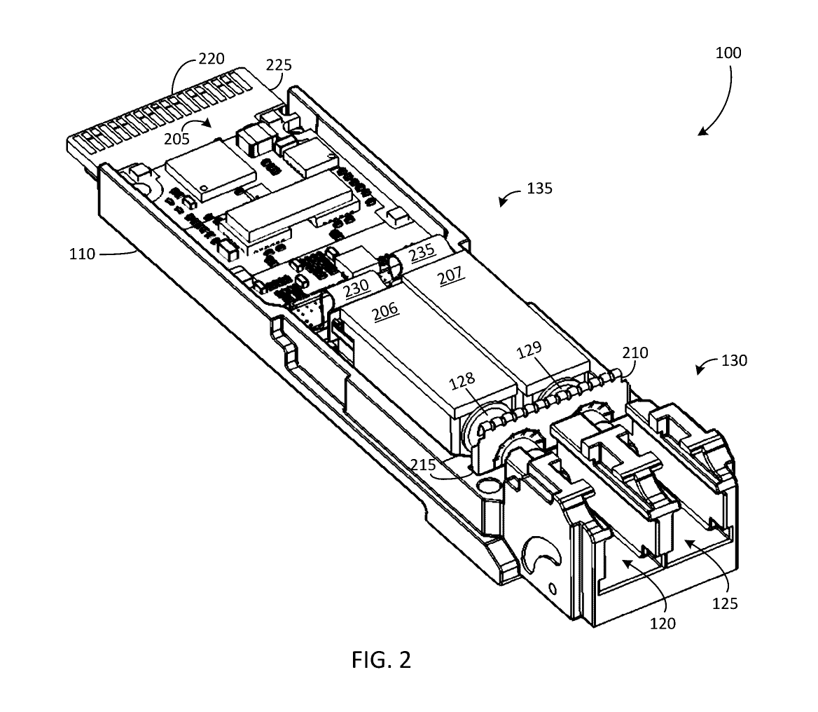

FIG. 2 shows a first perspective view of various exemplary components mounted in the lower housing portion 110 of the optical communications module 100. The various exemplary components include an electronic circuit assembly 205, a first optoelectronic module 206, a second optoelectronic module 207, and an EMI shield 210 in accordance with an illustrative embodiment of the disclosure. The electronic circuit assembly 205 includes various components that operate upon electrical signals of various frequencies. When these frequencies correspond to certain RF regions of the frequency spectrum, for example, GHz frequencies, EMI emissions can take place out of one or more components of the electronic circuit assembly 205. The EMI emissions can radiate out in various directions, including towards the first receptacle area 120 and the second receptacle area 125.

Each of the first optoelectronic module 206 and the second optoelectronic module 207 performs operations that include signal conversion between the optical domain and the electrical domain. For example, when the optical communications module 100 is configured to transmit optical signals out of the first optical port 128, the first optoelectronic module 206 converts electrical signals received from the electronic circuit assembly 205 into optical signals that are propagated out of the first optical port 128. On the other hand, when the optical communications module 100 is configured to receive an optical signal via the first optical port 128, the first optoelectronic module 206 converts the received optical signals into electrical signals that are then provided to the electronic circuit assembly 205.

In accordance with this illustrative embodiment, the EMI shield 210, which is configured for blocking EMI emissions radiating from the electronic circuit assembly 205 as well as any that may radiate out of the first optoelectronic module 206 and/or the second optoelectronic module 207, is inserted into a slot 215 that is provided in the lower housing portion 110. Further details pertaining to the EMI shield 210 are provided below with reference to other figures.

In this exemplary embodiment, the various components of the electronic circuit assembly 205 are mounted on a printed circuit board (PCB) 225. The PCB 225 can be a multilayer PCB and include a ground layer. The ground layer is connected to a set of ground pins that are a part of an edge connector 220. The edge connector 220 has other pins that are connected to various other components of the electronic circuit assembly 205 for purposes of conducting various electrical signals that are operated upon by the electronic circuit assembly 205. Such signals include power signals that are used to power the various components of the electronic circuit assembly 205.

When the optical communications module 100 is inserted into a host device (not shown) such as a router or a communications switch, the edge connector 220 mates with a corresponding connector in the host device. Each of the set of ground pins that are a part of an edge connector 220 makes contact with a matching set of ground pins in the corresponding connector of the host device. The ground pins located in the corresponding connector of the host device are connected to ground potential (typically via a chassis connection of the host device to what is known in the industry as “earth” ground). The set of ground pins located in the edge connector 220 thus get connected to ground potential, consequently grounding any EMI signals that enter the ground layer of the PCB 225.

Each of the first optoelectronic module 206 and the second optoelectronic module 207 is typically implemented in the form of a metal enclosure. The metal enclosure may be connected to the ground layer in the PCB 225 via a set of wires contained in one or both of a first ribbon cable 230 and a second ribbon cable 235. Thus, the metal enclosure of each of the first optoelectronic module 206 and the second optoelectronic module 207 is maintained at ground potential. The first optical port 128 and the second optical port 129 are each mounted on a respective wall of the first optoelectronic module 206 and the second optoelectronic module 207 as described below in further detail. Thus, the cylindrical body portion of each of the first optical port 128 and the second optical port 129 are maintained at ground potential, thereby operative to suppressing EMI emissions leaking from around a periphery of each of the first optical port 128 and the second optical port 129.

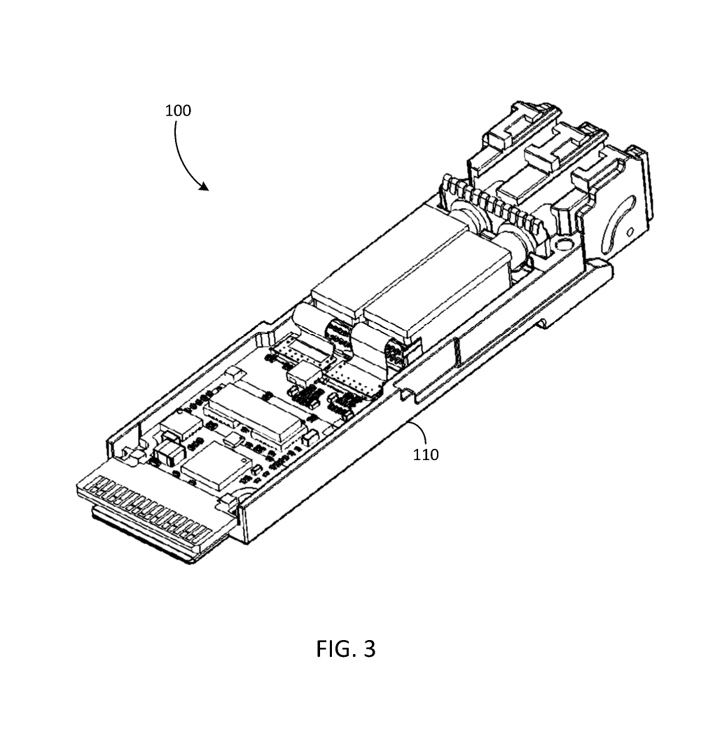

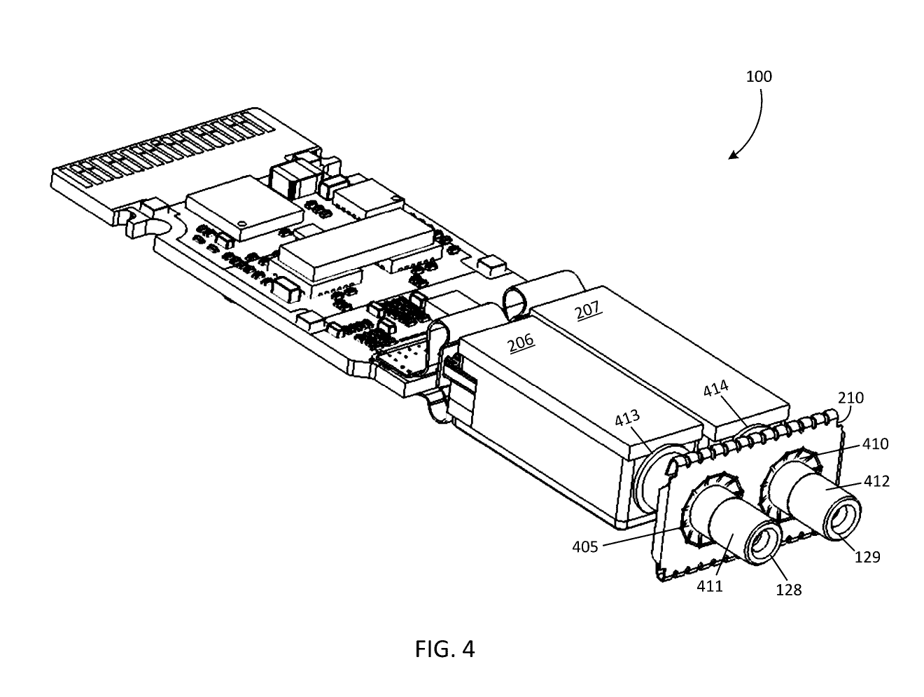

FIG. 3 shows a second perspective view of the various exemplary components mounted in the lower housing portion 110 of the optical communications module 100, while FIG. 4 shows a perspective view of the various exemplary components with the lower housing portion 110 removed.

With specific reference to FIG. 4, an elongated cylindrical body portion 411 of the first optical port 128 is slideably inserted through a first circular opening 405 formed in the EMI shield 210 while an elongated cylindrical body portion 412 of the second optical port 129 is slideably inserted through a second circular opening 410 that is also formed in the EMI shield 210. A mounting portion 413 of the first optical port 128 is fixedly attached to a mounting area in a wall of the first optoelectronic module 206. For some types of connectors, the mounting portion 413 of the first optical port 128 can include a threaded area (not shown) that is paired with a corresponding nut for fixedly attaching the first optical port 128 to the wall of the first optoelectronic module 206. A mounting portion 414 of the second optical port 129 is similarly attached to another mounting area of the wall of the second optoelectronic module 207.

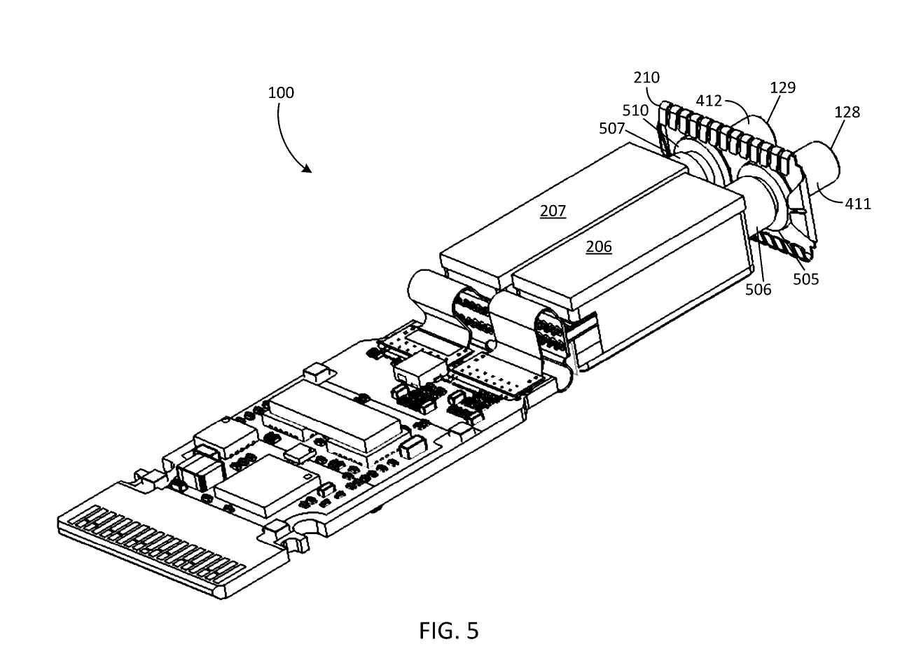

FIG. 5 shows another perspective view of the various exemplary components with the lower housing portion 110 removed. Attention is particularly drawn to a portion of the view pertaining to a back portion of the EMI shield 210. The first optical port 128 includes a second elongated cylindrical portion 506 that has a larger diameter than the first elongated cylindrical portion 411. The transition point between the first elongated cylindrical portion 411 and the second elongated cylindrical portion 506 is characterized by a first flange 505. The first flange 505 prevents the EMI shield 210 from sliding on to the second elongated cylindrical portion 506. Each of the first elongated cylindrical portion 411, the second elongated cylindrical portion 506, and the first flange 505 is made of metal. Thus, when EMI shield 210 is placed in contact with the first flange 505, EMI emissions blocked by the EMI shield 210 are routed to ground via the first flange 505 and the first optoelectronic module 206.

The second coaxial optical port 128 similarly includes a second elongated cylindrical portion 507 that has a larger diameter than the corresponding first elongated cylindrical portion 412 and further includes a second flange 510 that operates in conjunction with the EMI shield 210 in a manner similar to that described above with respect to the first flange 505.

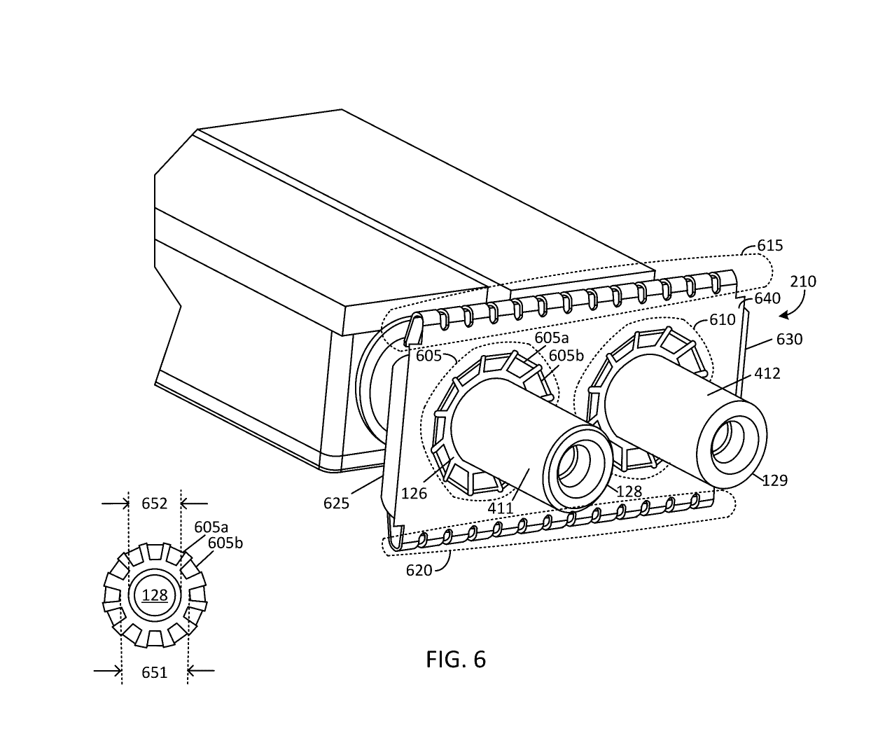

FIG. 6 shows an obverse-side close-up perspective view of the EMI shield 210 with the first coaxial optical port 128 and the second coaxial optical port 129 inserted through a respective one of the first circular opening 126 and the second circular opening 127 in the EMI shield 210. The EMI shield 210 can be manufactured as a stamped part from a sheet metal plate. In one example implementation, the EMI shield 210 is a part that is manufactured by applying a stamping procedure upon a stainless steel plate by using a progressive die, for example. The stamped part can then be plated with nickel (or a similar compound) to provide higher surface electrical conductivity. The stainless steel material provides strength to the EMI shield 210 while the nickel plating provides a desirable level of EMI shielding, especially with respect to frequencies or data rates in the RF region, such as, for example, data rates exceeding 10 Gigabits per second (Gb/sec). More particularly, the nickel plating provides the desirable level of EMI shielding by providing conductivity to EMI currents on the basis of a skin effect. The skin effect is particularly effective for conducting EMI current at high frequencies.

The manufacturing procedure described above is directed at producing an EMI shield 210 that not only includes the first circular opening 126 and the second circular opening 127, but also various resilient metal fingers. Specifically, the first circular opening 126 of the EMI shield 210 is characterized by a first annular array of resilient metal fingers 605 and the second circular opening 127 is characterized by a second annular array of resilient metal fingers 610. Each individual resilient metal finger in the first annular array of resilient metal fingers 605 is configured to press against the first flange 505 (FIG. 5), and each individual resilient metal finger in the second annular array of resilient metal fingers 610 is configured to press against the second flange 510 (FIG. 5) when the first optical port 128 and the second optical port 129 are cooperatively inserted through a respective one of the first circular opening 126 and the second circular opening 127 of the EMI shield 210.

Attention is drawn to a portion of FIG. 6 that shows an enlarged front profile view of the first optical port 128 inserted through the first circular opening 126. A diameter 651 of the first circular opening 126 is selected to be larger than a diameter 652 of the first optical port 128 in order to specifically prevent any of the resilient metal fingers of the first annular array of resilient metal fingers 605 from making contact with the elongated cylindrical body portion 411 of the first optical port 128. The resulting space provided between the elongated cylindrical body portion 411 and the resilient metal fingers of the first annular array of resilient metal fingers 605 provide a degree of freedom that permits various parts of the optical communications module 100 to be adjustably aligned with respect to each other such as, for example, when attaching the front housing portion 130 to the rear housing portion 135, or for adjusting the spacing between the first optical port 128 and the second optical port 129.

Furthermore, each of the individual resilient metal fingers of the first annular array of resilient metal fingers 605 incorporates a chamfer with respect to a major planar surface 640 of the EMI shield 210. For example, an illustrative first chamfer 605a is shown associated with a first resilient metal finger, and an illustrative second chamfer 605b is shown associated with a second resilient metal finger. The chamfer provided in each resilient metal finger of the first annular array of resilient metal fingers 605, coupled with the spring-like flexibility characteristics of the sheet metal from which the EMI shield 210 is manufactured, permits each resilient metal finger to provide positive contact force with the surface of the first flange 505. Each of the individual resilient metal fingers of the second annular array of resilient metal fingers 610 similarly incorporates a chamfer with respect to the major planar surface 640 of the EMI shield 210.

Each of the first annular array of resilient metal fingers 605 and the second annular array of resilient metal fingers 610 is further characterized by having an interdigital spacing between adjacent resilient metal fingers specifically defined on the basis of one or more EMI frequencies generated in the optical communications module 100. For example, the interdigital spacing can be selected to correspond to a fraction of a wavelength such as, for example, a fraction of the shortest wavelength corresponding to the EMI emissions generated when operating the electronic circuit assembly 205 at a data rate of 25 Gb/s. Such a fraction of wavelength can be, for example, one fifth or one tenth of a wavelength such as, for example, one fifth or one tenth of about 12 mm, or one fifth or one tenth of about 1.2 mm. In some example implementations, the interdigital spacing can be selected to correspond to fractions even smaller than one fifth or one tenth of a wavelength.

Turning now to another feature in accordance with the disclosure, the EMI shield 210 that is described in this exemplary embodiment has four outside peripheral edges. A top peripheral edge of the EMI shield 210 includes a first linear array of resilient metal fingers 615, and a bottom peripheral edge of the EMI shield 210 includes a second linear array of resilient metal fingers 620. As for the two sides, a first side edge of the EMI shield 210 includes a first bifurcated resilient metal member 625, and an opposing side edge of the EMI shield 210 includes a second bifurcated resilient metal member 630. Further details pertaining to the various resilient metal members of the EMI shield 210 are described below with reference to other figures.

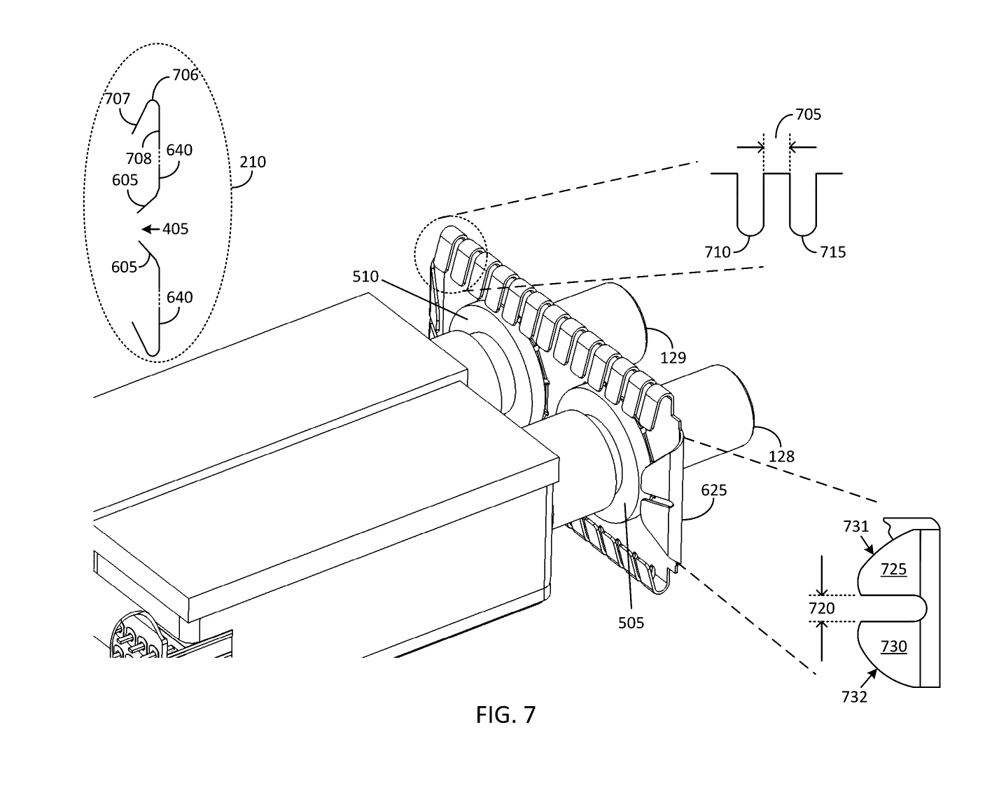

FIG. 7 shows a reverse-side close-up perspective view of the EMI shield 210 that is shown in FIG. 6. As described above, the first annular array of resilient metal fingers 605 associated with the first circular opening 126 provides electrical contact by pressing against a front surface of the first flange 505. The second annular array of resilient metal fingers 610 associated with the second circular opening 127 provides electrical contact by pressing against a front surface of the second flange 510 as well. An interdigital spacing between adjacent resilient metal fingers of the first linear array of resilient metal fingers 615 is particularly defined in accordance with the disclosure, with respect to one or more EMI frequencies generated in the optical communications module 100. The adjacent resilient metal fingers of the second linear array of resilient metal fingers 620 is also particularly defined in accordance with the disclosure, with respect to one or more EMI frequencies generated in the optical communications module 100.

To elaborate upon this aspect, attention is drawn to a first portion of FIG. 7 that shows an enlarged profile view of adjacent resilient metal fingers 710 and 715 of the first linear array of resilient metal fingers 615. The interdigital spacing 705 between adjacent resilient metal fingers 710 and 715 is selected on the basis of one or more EMI frequencies generated in the optical communications module 100 (for example, by the electronic circuit assembly 205 shown in FIG. 2). In a first exemplary implementation, the interdigital spacing 705 is selected to correspond to a fraction of a wavelength (for example, a fraction of a wavelength corresponding to an EMI emission generated when operating the electronic circuit assembly 205 at a data rate of 25 Gb/s). The fraction of the wavelength can be, for example, one fifth or one tenth of the wavelength or even smaller. The interdigital spacing 705 between adjacent resilient metal fingers of the first linear array of resilient metal fingers 615 can be the same as, or different than, the interdigital spacing between adjacent resilient metal fingers of each (or both) of the first annular array of resilient metal fingers 605 and the second annular array of resilient metal fingers 610.

Attention is next drawn to a second portion of FIG. 7 that shows a cross-sectional view of the EMI shield 210. The EMI shield 210 includes the major planar surface 640 (shown in FIG. 6) and two individual resilient metal fingers of the first annular array of resilient metal fingers 605 that define in part, the first circular opening 405 formed in the EMI shield 210. Each of the two individual resilient metal fingers of the first annular array of resilient metal fingers 605 includes a chamfer as described above. One example resilient metal finger among the multiple fingers of the first linear array of resilient metal fingers 615 (shown in FIG. 6) formed on the top peripheral edge of the EMI shield 210 has a U-shaped profile with a resilient extension portion 707 that extends outwards from a chamfered portion 706. The providing of the chamfered portion 706 urges the resilient extension portion 707 away from the major planar surface 708 of the EMI shield 210. The major planar surface is the reverse major surface to the major planar surface 640 that is shown in FIG. 6.

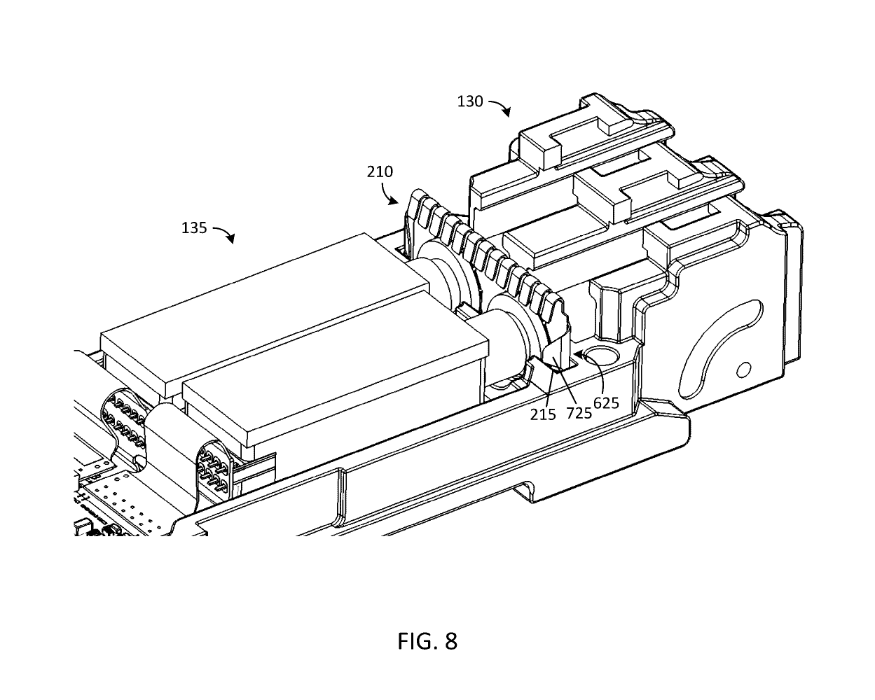

Attention is next drawn to a third portion of FIG. 7 that shows an enlarged profile view of the first bifurcated resilient member 625. The first bifurcated resilient member 625 includes a first resilient section 725 and a second resilient section 730. A width of each of the first resilient section 725 and the second resilient section 730 is larger than a width of each of the resilient metal fingers in any of the first linear array of resilient metal fingers 615, the second linear array of resilient metal fingers 620, the first annular array of resilient metal fingers 605, or the second annular array of resilient metal fingers 610. The larger width is a result of limiting the first bifurcated resilient member 625 to two distinct sections rather than having a large number of resilient metal fingers. This limiting to two distinct sections is carried out in order to provide an advantage during assembly of the EMI shield 210 inside the optical communications module 100. Furthermore, the second resilient section 730 includes a sloped leading edge 732 that assists insertion of the second bifurcated resilient member 730 into a slot, as described below in more detail with reference to FIG. 8. The first resilient section 725 includes a sloped leading edge 731 for a similar purpose.

In one example implementation, an interdigital spacing 720 between the first resilient section 725 and the second resilient section 730 of the first bifurcated resilient member 625 is selected on the basis of one or more EMI frequencies generated in the optical communications module 100 (for example, in the electronic circuit assembly 205 shown in FIG. 2). However, in another example implementation, the interdigital spacing 720 between the first resilient section 725 and the second resilient section 730 can be selected on the basis of other factors, such as, for example, mechanical mounting factors. This aspect is described below in more detail with respect to FIG. 8. The details provided above with respect to the first bifurcated resilient member 625 is equally applicable to the second bifurcated resilient member 630 and will not be repeated herein in the interest of brevity.

FIG. 8 shows a close-up view of the EMI shield 210 with the second resilient section 730 of the first bifurcated resilient member 625 inserted into the slot 215 provided in the lower housing portion 110 of the optical communications module 100. The first resilient section 725 of the first bifurcated resilient member 625 is similarly seated in a corresponding slot provided in the upper housing portion 105 (shown in FIG. 1). The sloped leading edge of the second resilient section 730 assists insertion of the first bifurcated resilient member 625 into the slot 215. Furthermore, it can be understood that it is easier to insert, vertically downwards, a singular element such as the second resilient section 730 into the slot 215, rather than attempting to insert into the slot 215, multiple elements, such as, for example, multiple resilient metal fingers similar to the ones provided in each of the first linear array of resilient metal fingers 605 and the second linear array of resilient metal fingers 610.

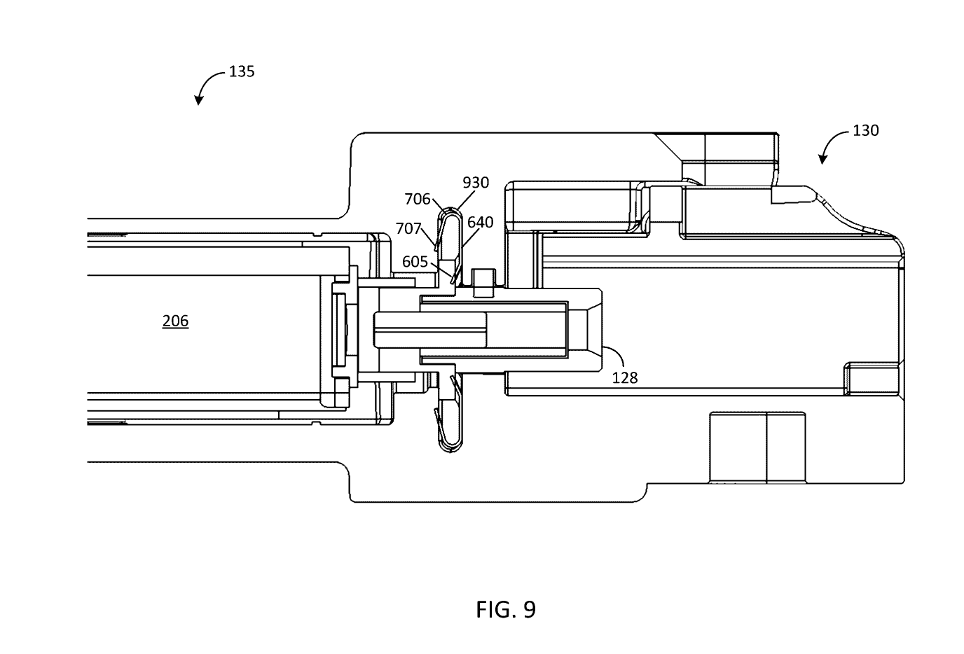

FIG. 9 shows a cross-sectional side view of the EMI shield 210 mounted inside the optical communications module 100 in accordance with the disclosure. When seated inside the optical communications module 100, the resilient extension portion 707 of the EMI shield 210 presses against a first wall portion inside the slot 930, and the major planar surface 640 of the EMI shield 210 sits flush against an opposing second wall portion inside the slot 930. Each of the first wall portion and the opposing second wall portion of the slot 930 is a metal wall thus providing electrical conductivity to the EMI shield 210 when the EMI shield 210 is placed inside the optical communications module 100.

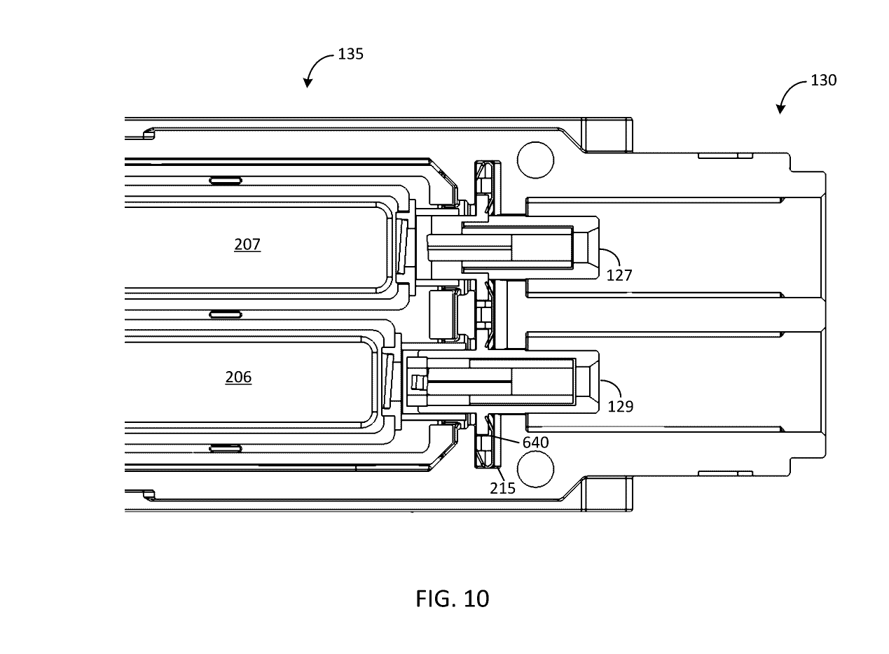

FIG. 10 shows a cross-sectional top view of the EMI shield 210 mounted inside the optical communications module 100 in accordance with the disclosure. A first resilient section of the first bifurcated resilient member 625, which is shown inserted into the slot 215, presses against a first wall portion inside the slot 215. The first wall portion is composed of metal and provides providing electrical conductivity to the EMI shield 210 when the EMI shield 210 is placed inside the optical communications module 100.

In summary, it should be noted that the invention has been described with reference to a few illustrative embodiments for the purpose of demonstrating the principles and concepts of the invention. It will be understood by persons of skill in the art, in view of the description provided herein, that the invention is not limited to these illustrative embodiments. For example, the invention has been described with respect to a rectangular shaped EMI shield 210 that is defined with respect to a first optical port 128 and a second optical port 129. In other embodiments, the EMI shield can have shapes other than a rectangular shape and can be defined with respect to less than, or more than, two optical ports. Persons of skill in the art will understand that many such variations can be made to the illustrative embodiments without deviating from the scope of the invention.

What is claimed is:

1. An optical communications module comprising:
an enclosure containing an electronic circuit assembly; and
an electromagnetic interference (EMI) shield mounted inside the enclosure, the EMI shield comprising a first opening configured to accommodate a first optical port inserted therethrough, the first opening characterized by a first annular array of resilient metal fingers arranged to press against a metal portion of the first optical port for suppressing EMI emissions leaking from around a periphery of the first optical port, the EMI shield further including at least a first peripheral edge incorporating a linear array of resilient metal fingers arranged to press against a metal portion inside the enclosure.

2. The optical communications module of claim 1, wherein the EMI shield further comprises a second opening configured to accommodate a second optical port inserted therethrough, the second opening characterized by a second annular array of resilient metal fingers arranged to press against a metal portion of the second optical port for suppressing EMI emissions leaking from around a periphery of the second optical port.

3. The optical communications module of claim 2, wherein the first optical port is substantially similar to the second optical port.

4. The optical communications module of claim 3, wherein each of the metal portion of the first optical port and the metal portion of the second optical port is a portion of a metal flange of a respective one of the first optical port and the second optical port.

5. The optical communications module of claim 1, wherein an interdigital spacing in the linear array of resilient metal fingers is defined on the basis of a wavelength associated with an EMI radiation from the electronic circuit assembly.

6. The optical communications module of claim 5, wherein the interdigital spacing in the linear array of resilient metal fingers is one of equal to or less than one fifth of the wavelength associated with the EMI radiation.

7. The optical communications module of claim 6, wherein the enclosure comprises an upper portion and a lower portion and wherein a second peripheral edge that is oriented orthogonal to the first peripheral edge of the EMI shield incorporates a bifurcated resilient member that includes a first resilient section and a second resilient section, the bifurcated resilient member adapted for insertion of one of the first resilient section or the second resilient section into a first slot in the lower portion of the enclosure and the other one of the first resilient section or the second resilient section into a second slot in the upper portion of the enclosure.

8. The optical communications module of claim 1, wherein an interdigital spacing in the first annular array of resilient metal fingers is defined on the basis of a wavelength associated with an EMI radiation from the electronic circuitry.

9. The optical communications module of claim 8, wherein the interdigital spacing in the first annular array of resilient metal fingers is one of equal to or less than one fifth of the wavelength associated with the EMI radiation.

10. A communications module:
an enclosure housing an electronic circuit assembly; and
a stamped metal plate mounted inside the enclosure, the stamped metal plate comprising a linear array of resilient metal fingers that constitutes a peripheral edge of the stamped metal plate, the stamped metal plate further comprising an opening characterized by an annular array of resilient metal fingers that constitutes an inner edge of the opening, and wherein at least one of: a) an interdigital spacing in the linear array of resilient metal fingers or b) an interdigital spacing in the annular array of resilient metal fingers is defined on the basis of a wavelength associated with an EMI radiation from the electronic circuit assembly.

11. The communications module of claim 10, wherein the at least one of: a) an interdigital spacing in the linear array of resilient metal fingers or b) an interdigital spacing in the annular array of resilient metal fingers is one of equal to or less than one fifth of the wavelength associated with the EMI radiation.

12. The communications module of claim 10, wherein the circular opening is configured to accommodate an optical port inserted therethrough, and wherein an end portion of each of the annular array of resilient metal fingers is arranged to press against a metal flange of the optical port.

13. The communications module of claim 12, wherein the optical port comprises a cylindrical body, wherein a diameter of the circular opening in the stamped metal plate is larger than an outside diameter of the cylindrical body, and wherein the diameter of the circular opening is selected on the basis of preventing the end portion of each of the annular array of resilient metal fingers from making contact with the cylindrical body of the optical port when the end portion of each of the annular array of resilient metal fingers presses against the flange of the optical port.

14. The communications module of claim 10, wherein the enclosure comprises an upper portion and a lower portion and wherein a second peripheral edge that is oriented orthogonal to the first peripheral edge of the stamped metal plate incorporates a bifurcated resilient member that includes a first resilient section and a second resilient section, the bifurcated resilient member adapted for insertion of one of the first resilient section or the second resilient section into a first slot in the lower portion of the enclosure and the other one of the first resilient section or the second resilient section into a second slot in the upper portion of the enclosure.

15. The communications module of claim 14, wherein the stamped metal plate is a nickel-coated steel plate, the nickel coating of the nickel-coated steel plate operative to minimize contact impedance when the stamped metal plate makes contact with one or more metal portions of the enclosure, and to provide electrical conductivity to skin effect currents generated by EMI radiation from the electronic circuit assembly.

16. A communications module comprising:
an enclosure housing an electronic circuit assembly; and
a rectangular stamped metal plate located inside the enclosure, the rectangular stamped metal plate having a linear array of resilient metal fingers constituting each of two longer edges of the rectangular stamped metal plate, the linear array of resilient metal fingers having an interdigital spacing defined on the basis of at least a first wavelength associated with an EMI radiation from the electronic circuit assembly, the rectangular stamped metal plate further having a bifurcated resilient member constituting each of two shorter edges of the rectangular stamped metal plate, the bifurcated resilient member adapted for insertion of one of a first resilient section or a second resilient section into a first slot in the lower portion of the enclosure and the other one of the first resilient section or the second resilient section into a second slot in the upper portion of the enclosure.

17. The communications module of claim 16, wherein the bifurcated resilient member consists of the first resilient section and the second resilient section.

18. The communications module of claim 16, wherein each of the linear array of resilient metal fingers is configured to press against one or more metal portions located inside the enclosure, and wherein the interdigital spacing in the linear array of resilient metal fingers is one of equal to or less than one fifth of the wavelength associated with the EMI radiation.

19. The communications module of claim 16, wherein the rectangular stamped metal plate further includes a circular opening characterized by an annular array of resilient metal fingers, the annular array of resilient metal fingers having an interdigital spacing defined on the basis of at least a second wavelength associated with the EMI radiation from the electronic circuitry.

20. The communications module of claim 19, wherein the interdigital spacing in the annular array of resilient metal fingers is different than the interdigital spacing in the linear array of resilient metal fingers.
